(19) United States
(12) Patent Application Publication
(10) Pub. No.: US 2002/0189062 A1
(43) Pub. Date: Dec. 19, 2002

(54) Manufacturing method for a high quality film bulk acoustic wave device

(75) Inventors: Chung-Hsien Lin, Cha-I-City (TW); Ju-Mei Lu, Ma-Kung City (TW); Shu-Hui Tsai, Hsin-Chu City (TW); Chenkuo Lee, Hsin-Chu City (TW)

Correspondence Address: BRUCE H. TROXELL, SUITE 1404, 5205 LEESBURG PIKE, FALLS CHURCH, VA, 22041, US

(73) Assignee: ASIA PACIFIC MICROSYSTEMS, INC.

(21) Appl. No.: 10/134,369

(22) Filed: Apr. 30, 2002

(30) Foreign Application Priority Data
Jun. 15, 2001 (TW) 090114538

(51) Int. Cl. H04R 17/00; H05K 3/02

(52) U.S. Cl. 29/25.35; 29/831; 29/846

(57) ABSTRACT

A manufacturing method for a high quality film bulk acoustic wave device, wherein a lower electrode protecting layer is partially defined or not applied, thus the quality factor of the bulk acoustic wave device is improved.

### Background of the Invention

1. Field of the Invention

The present invention relates to a manufacturing method for a bulk acoustic wave device, especially to a bulk acoustic wave device and the manufacturing method thereof, wherein a lower electrode protecting layer is partially defined or not applied, thus the quality factor of the bulk acoustic wave device is improved.

2. Description of the Related Art

The mobile communication is so vigorously developed that speed up the requirement of the RF (Radio frequency) wireless electronic device. The mobile ability of the wireless communication product is depended on the size of device and the lifetime of battery. Also the devices manufacturers are dedicated to develop the tiny, cheaper and the more well performance devices. The finally step to microminiaturize the device is to integrate it with IC to form a system on chip (SOC). Presently, in the RF front-end of the wireless system, one of the devices that still can not be integrated with the IC, is R-F front-end filter. In the future, the RF front-end filter will be the occupied space and the necessary device in the double, triple or multiple frequency standards. The multiplexer obtained by associating the RF switch with RF front-end filter would be the key to decide the communication quality.

The ordinarily used RF front-end filter is the surface acoustic filter. In the past, the surface acoustic filter is not only to be the RF front-end filter but also to be the channel selective filter in the IF (intermediate-frequency) band. However, in accompany with the development of the direct conversion transformation technique (that is, the zero-IF or near zero-IF technique), it does not need more analog IF filter, so the application of the surface acoustic filter can only be extended to the RF filter. But the surface acoustic filter itself has the larger insertion loss and it has worse power dissipation stand. In the past, the insertion loss standard in the use of IF band selective filter is not rigorous, and the IF band belongs to the RF back-end so that it is not necessary to use a well power dissipation stand. But now, if it is used in the RF front-end, the aforementioned both standards will be the problem to the surface acoustic filter.

In order to solve the problem, at 1998 the Sumitomo Electric company in Japan disclosed the deposition of interdigital transducer (IDT) on the zinc oxide/diamond/silicon substrate. It used the high Young's modulus and well thermal conductivity of the Diamond, so the IDT on the compound substrate could stand about 35 dBm dissipation and still could maintain the well linearity. But it is rather expensive about the Diamond substrate, and the line pitch of the IDT is below micrometer, and it has the lower error tolerance and expensive in the equipment investment.

The other product of RF filter is the Low Temperature Cofired Ceramics (LTCC). The Low Temperature Cofired Ceramics (LTCC) owns the best benefit of higher stand to the RF dissipation. However, it still has other problems that have to be solved, such as: the difficulty in measurement, and not easy to get the ceramic powder from the upper company, and the ceramic happened the shrinkage phenomenon in the manufacturing processes that the deviations of products were caused and it is difficult to modify.

3, Description of the Prior Art

Recently, the technique about the bulk acoustic wave filter device, such as the Film Bulk Acoustic Resonator (FBAR) device (refer to the U.S. Pat. No. 6,060,818) developed by HP company, and the Stack Bulk Acoustic Resonator (SBAR) device (refer to the U.S. Pat. No. 5,872,493) provided by Nokia company, which could diminish the volume of the high efficiency filter product, and it could operate in 400 MHz to 10 GHz frequency band. The duplexer using in the CDMA mobile phone is one kind of said filter product. The size of the bulk acoustic wave device is just a part to the ceramic duplexer, and it owns better rejection, insertion loss, and power management ability than the surface acoustic filter. The combination of those properties could make the manufacturer produce high performance, up-to-date, and mini-type wireless mobile communication equipment. The bulk acoustic wave device is a semiconductor technique, so it could integrate the filter into the RFIC, and to form the system on chip (SOC).

Although the SBAR device is not necessary to form a vacant architecture below the bottom of the oscillator, it has to deposit the multi-layer film that is difficult in the process and detrimental to integrate, and it is finite to be selected as the Bragg reflection layer material, so the device yield is relatively low.

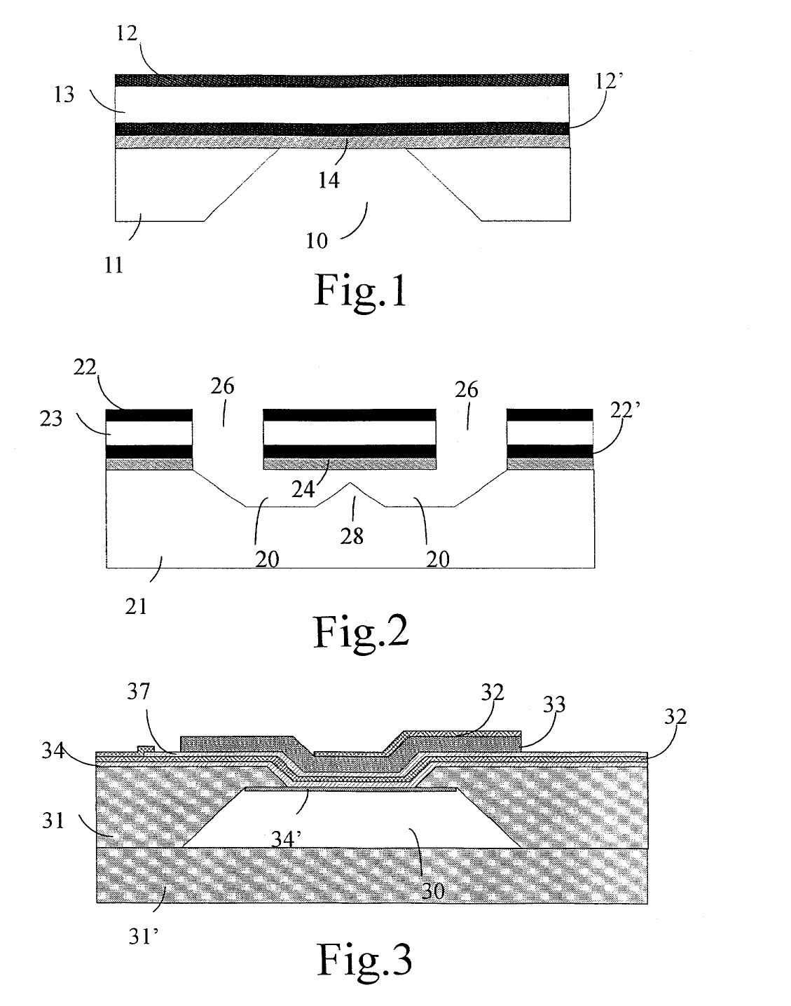

It is necessary to form a cavity below the resonator in the FBAR device. In general, a developed way is to fabricate the cavity by backside etching or front-side etching the substrate. As the backside etching is being proceeded, the density of the devices thereof is restricted greatly. As shown in FIG. 1, a supporting layer 14, a lower electrode pattern 12′, a piezoelectric material layer 13, and an upper electrode metal pattern 12 are formed sequentially. Thereafter, backside etching is proceeded to form a cavity 10 in the desired resonator region. It needs more time for backside etching since the etching depth of backside etching is relatively deep; and it also needs quite a long time for front-side etching since undercut etching is performed at crystalline planes that have a slow etching rate to excavate the substrate below the resonator. As shown in FIG. 2, a supporting layer 24, a lower electrode pattern 22′, a piezoelectric material layer 23, and an upper electrode metal pattern 22 are formed sequentially onto the substrate 21. Thereafter, front-side etching is proceeded to form a cavity 20 on the desired resonator region, and the silicon substrate residue 28 is remained.

FIG. 3 shows the bulk acoustic wave device fabricated by bonding technique by HP Company. Firstly, the chip 31 is ground in order to reduce its thickness, so that the etching time can be reduced. Nevertheless, complicated and time consumed process techniques are required, such as grinding and waver bonding, etc. Moreover, any materials on the acoustic path may influence the properties of the bulk acoustic wave device (refer to the U.S. Pat. No. 5,789,845 and the doctoral dissertation “A Sealed Cavity Thin-Film Acoustic Resonator Process for RF Bandpass Filters” disclosed by Joseph J. Lutsky at 1997). But, in the construction formed by this technique, there is a lower electrode protecting layer 37 between the lower electrode 32′ and the piezoelectrical material 33, thus the properties of the devices are deteriorated.

Besides, in general, there is a problem with the FBAR devices while front-side etching is proceeding. That is, the upper electrode patterns 22, the lower electrode patterns 22′, the piezoelectric material layers 23 and the supporting layers 24 have to be etched in order to form etching windows 26, so that the etchant can pass through the etching windows 26 to form the cavity 20. However, it is difficult to form patterns onto the piezoelectric material layers. The conventional way is by metal mask, ion milling dry etching, or laser machining. Such methods have difficulties in cost and processes, and large etching area and etching uniformity are very difficult to be achieved.

### SUMMARY OF THE INVENTION Accordingly, the present invention is objected to improve the above-mentioned defects of conventional art.

Therefore, it is an object of the present invention to provide a method for manufacturing the film bulk acoustic wave device, wherein the quality factor of the bulk acoustic device is improved.

Another object of the present invention is to provide a method for manufacturing a film bulk acoustic wave device, wherein the quality factor of the bulk acoustic device is improved, and no need for backside etching and depositing the protecting layer of the lower electrode.

A further another object of the present invention is to provide a method for manufacturing a film bulk acoustic wave device, wherein the quality factor of the bulk acoustic device is improved, and no need for backside etching and depositing the protecting layer of the lower electrode, and the materials having high selection with aluminum nitride (AlN) are not used.

To accomplish the above-mentioned objects, in the method for manufacturing a film bulk acoustic wave device according to the present invention, a protecting layer for the lower electrode is partially defined, thus the piezoelectrical layer can be contacted directly with the lower electrode.

To accomplish the above-mentioned objects, in the method for manufacturing a film bulk acoustic wave device according to the present invention, a material having better etching selectivity with AlN film layer is used as a lower electrode, thus there is no need for depositing the protecting layer of the lower electrode.

To accomplish the above-mentioned another objects, in the method for manufacturing a film bulk acoustic wave device according to the present invention, an etching machine having an end point detector is used, or the lift-off technique for defining the AlN film layer is applied, thus there is no need for depositing the protecting layer of the lower electrode.

BRIEF DESCRIPTION OF THE DRAWINGS

The above objectives and advantages will become more apparent with explanation of the accompanying drawings.

FIG. 1 is a perspective view showing the bulk acoustic wave device that is backside etched according to the prior art.

FIG. 2 is perspective view showing the bulk acoustic wave device that is front-side etched according to the prior art.

FIG. 3 is a perspective view showing the bulk acoustic wave device using the wafer bonding technique according to the prior art.

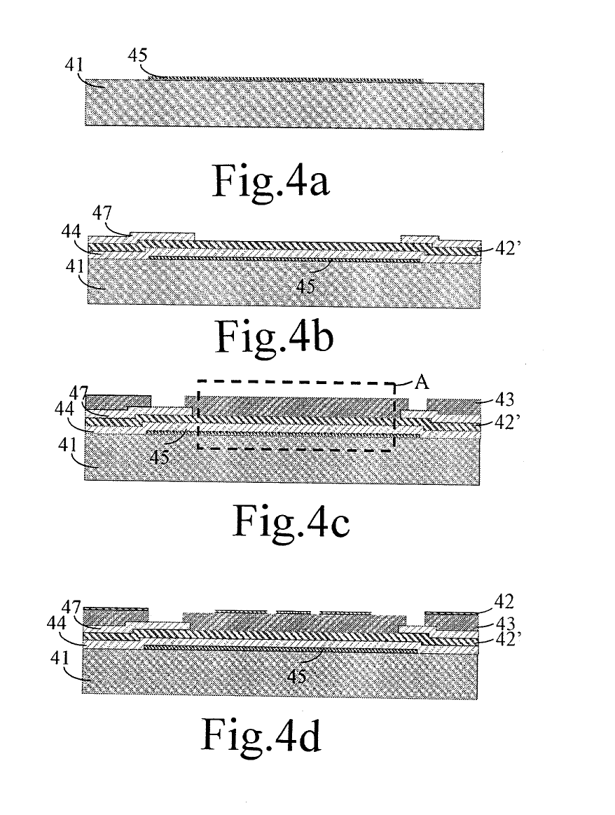

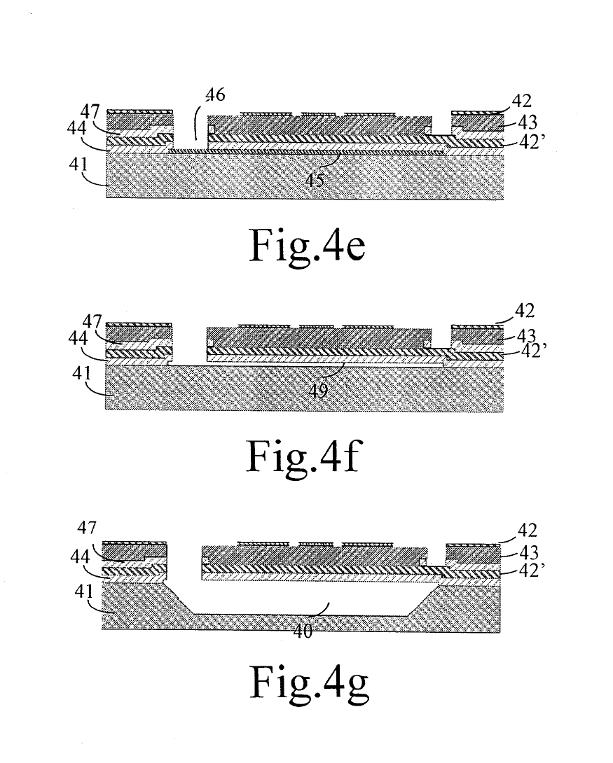

FIGS. 4a through 4g are perspective views showing a lower electrode protecting layer is partially defined and applied as a piezoelectrical layer and an etching selectivity interlayer of the lower electrode according to the first embodiment of the present invention.

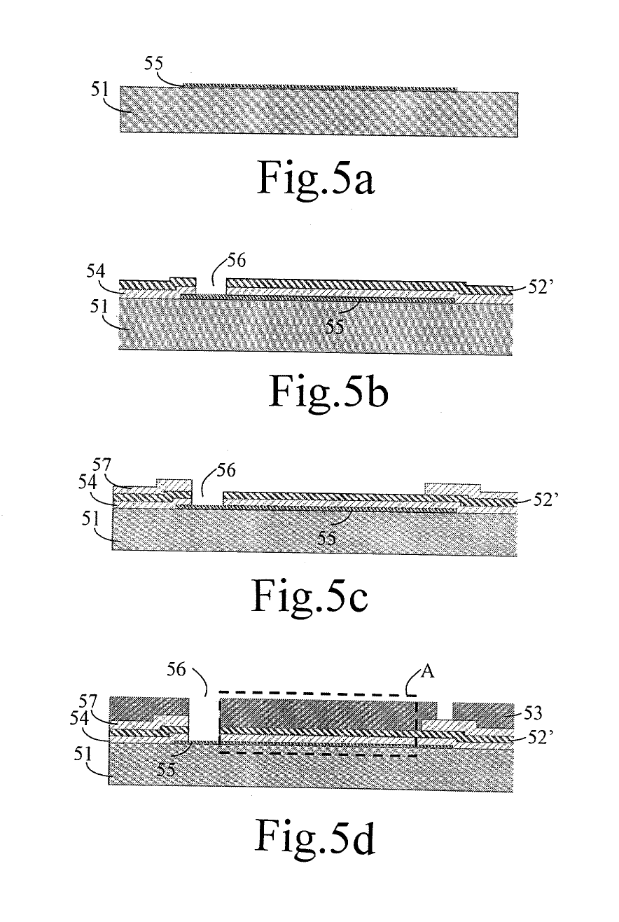

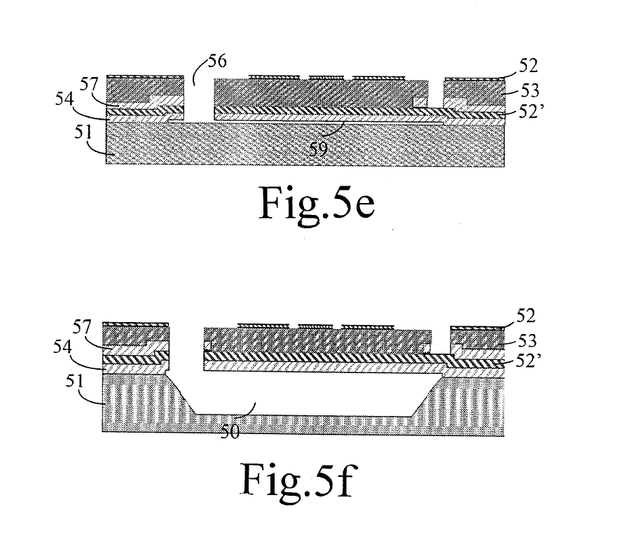

FIGS. 5a through 5f are perspective views showing a lower electrode protecting layer is partially defined and applied as a piezoelectrical layer and an etching selectivity interlayer of the lower electrode according to the second embodiment of the present invention.

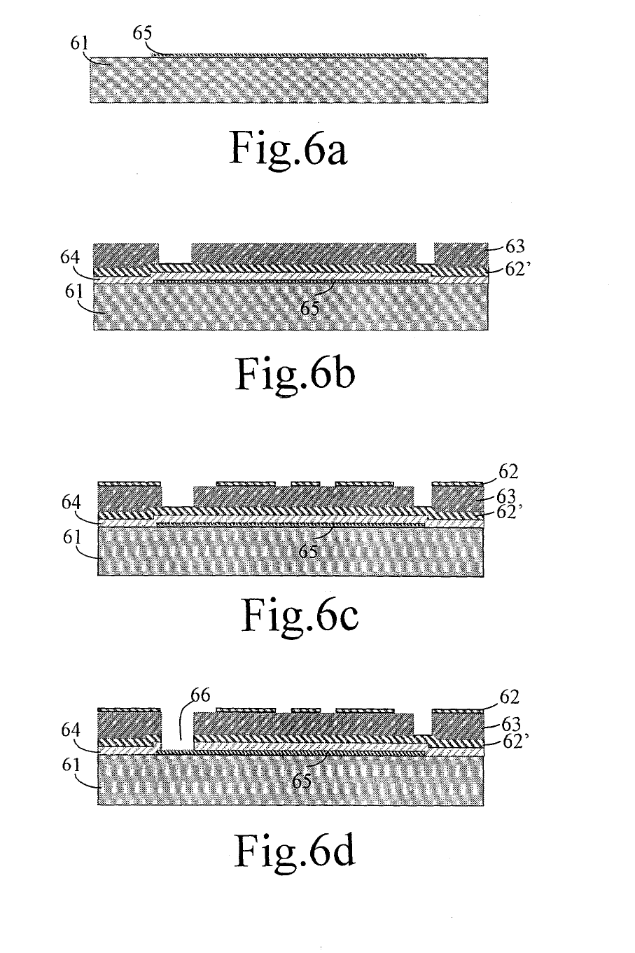

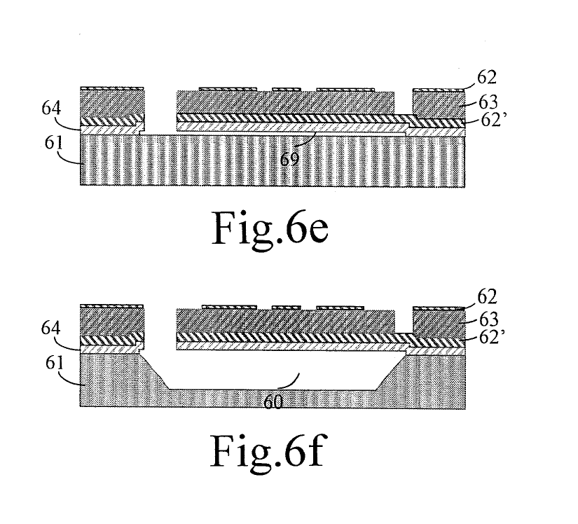

FIGS. 6a through 6f are perspective views showing a material having better etching selectivity with AlN is used as the lower electrode according to the third embodiment of the present invention.

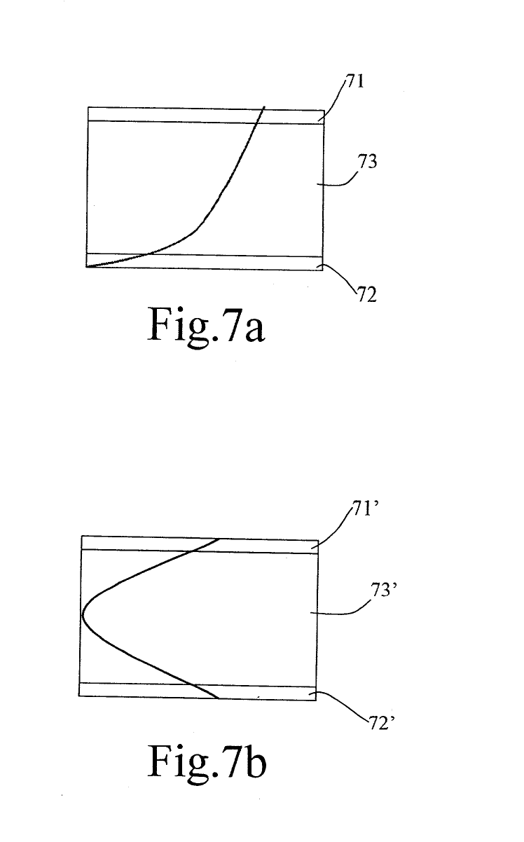

FIGS. 7a and 7b show the oscillating statuses during the bulk acoustic wave device is being operated at quarter wavelength and semi wavelength.

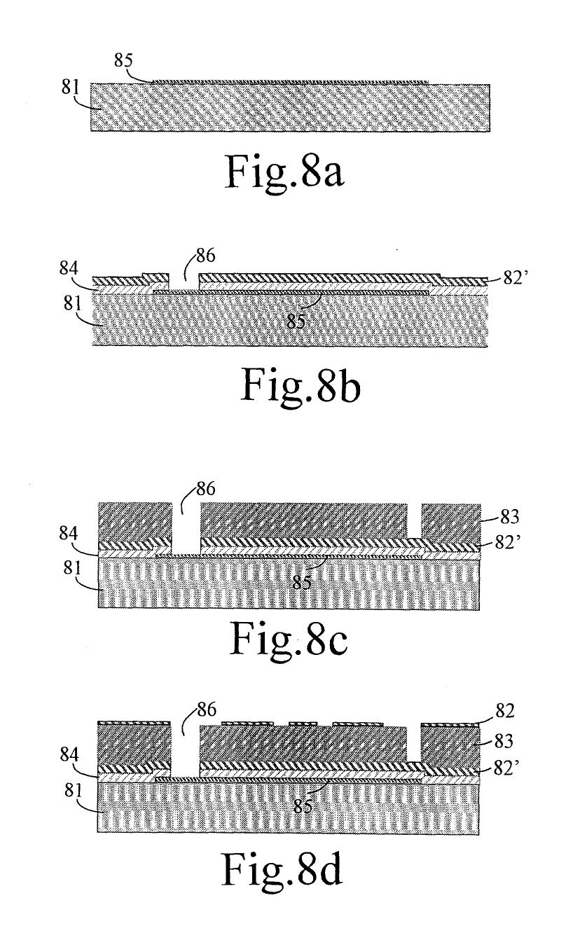

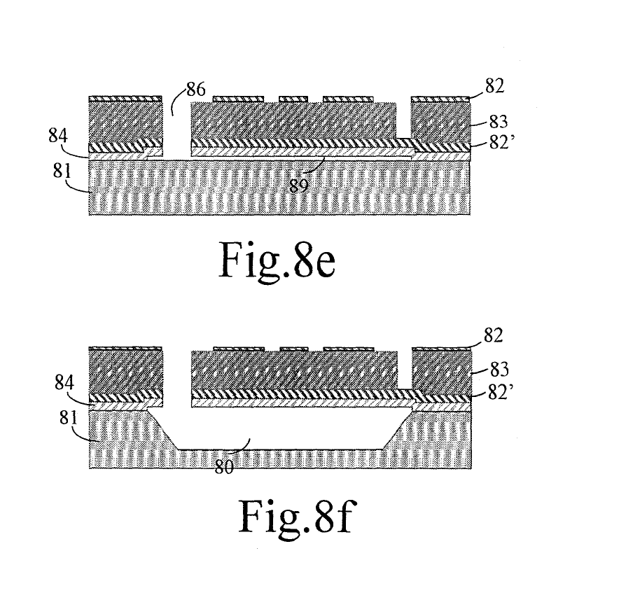

FIGS. 8a through 8f are perspective views showing a material having better etching selectivity with AlN is used as the lower electrode according to the fourth embodiment of the present invention.

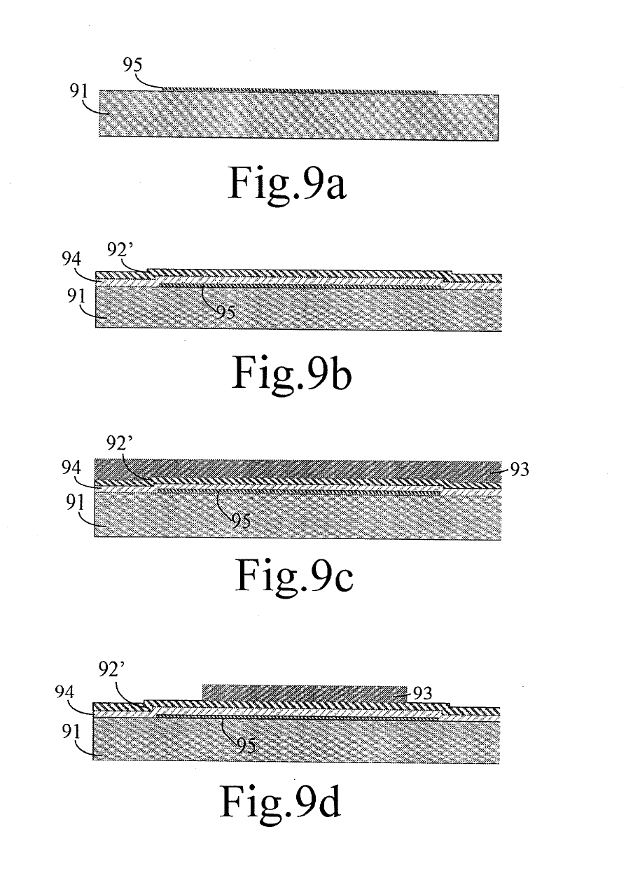

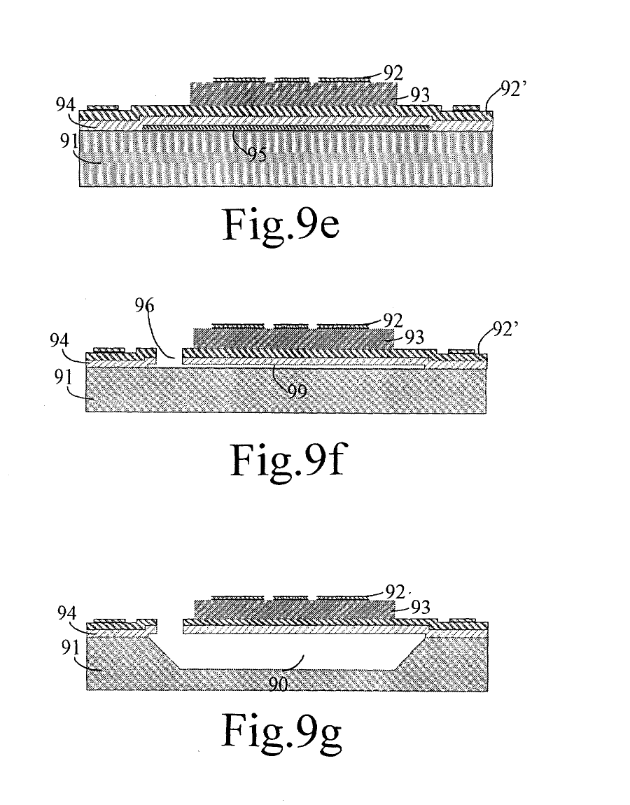

FIGS. 9a through 9g are perspective views showing an etching machine with an end point detector is applied, or an AlN layer is applied by the lift-off technique, so that no need for depositing the lower electrode protecting layer according to the fifth embodiment of the present invention.

### DETAILED DESCRIPTION OF THE PREFERRED EMBODIMENT

FIGS. 1 through 3 are the perspective views of the bulk acoustic device using backside etching and front-side etching according to the conventional technology and have been described already, so they are not repeated. FIGS. 4a through 4g are perspective views showing a lower electrode protecting layer is partially defined and applied as a piezoelectrical layer and an etching selectivity interlayer of the lower electrode according to the first embodiment of the present invention. In the whole process, it has the advantages as integrating surface micromaching and bulk micromaching. There is no etching selectivity interlayer on the acoustic path that influence to the quality factor of the bulk acoustic wave device. Moreover, it enables a good quality of the following piezoelectrical layer and the upper electrode layer film. As shown in FIG. 4a, the bulk acoustic device can be formed on a substrate 41. First, a sacrificial layer film 45 is deposited on the substrate and defined by micro-image technique; the geometric size of this sacrificial layer will be a determinant of size of the substrate cavity 40. Then, as shown in FIG. 4b, a supporting layer 44, a lower electrode pattern 42′, a lower electrode protecting layer 47 are formed sequentially on this construction. Since aluminum nitride (AlN) is usually used for the piezoelectrical layer, aluminum (Al) is usually used for the lower electrode, and their relative etching selectivity is low, so it is difficult to etch the AlN without damaging Al. Therefore, a lower electrode-protecting layer 47 is used as an etch-terminated layer for AlN according to the present embodiment. The lower electrode protecting layer 47 can be made of a material for dielectrical layer having better etching selectivity with the said two materials, such as silicon oxide (Si₃N₄) or silica (SiO₂) etc., in order to be used as the etching-stop layer for AlN. Then, the lower electrode-protecting layer 47 is defined by micro-image technique, thus the lower electrode 42′can be contacted with the piezoelectrical layer later on. Meanwhile, various etchants or various etching gases can be selected according to various lower electrode-protecting layers. Afterwards, as shown in FIG. 4c, a piezoelectrical 43 is deposited and the shape thereof is defined by micro-image technique. Since there is no lower electrode protecting layer 47 between the operation region A of the bulk acoustic wave device of the piezoelectrical layer 43 and the lower electrode 42′, comparing with the prior techniques, the acoustic loss caused by the acoustic wave passing through the lower electrode-protecting layer 47 can be reduced according to the present embodiment. Then, as shown in FIG. 4d, an upper electrode 42 is deposited and the shape thereof is defined. At this step, in order to prevent the surface of the piezoelectrical layer 43 from being damaged by the etchant of the upper electrode, the shape of the upper electrode can be defined by the lift-off technique. Afterwards, as shown in FIG. 4e, the etching window 46 of the etching sacrificial layer is opened, and thus a part of the surface of the sacrificial layer 45 is exposed. Then, as shown in FIG. 4f, the sacrificial layer 45 can be removed by dry etching or wet etching, and a sacrificial layer cavity 49 is generated. Finally, as shown in FIG. 4g, the substrate 41 is etched by using front-side etching method, thus a substrate cavity 40 is generated, and the construction of the bulk acoustic wave device is released, so the whole fabrication of the bulk acoustic wave device is completed. According to the present embodiment, the sacrificial layer 45 is not required to be too thick, therefore, the deposition time of the sacrificial layer 45 can be saved and its smoothness can be ensured. Thus, it is advantageous to the follow-up deposition of the electrode 42 and the piezoelectrical layer 43. The material of the sacrificial layer 45 can be the same as that of the substrate, so they can be applied with the same etchant and process. For example, while a silicon substrate is being applied, polycrystalline silicon or non-crystalline silicon can be used for the sacrificial layer 45. Another, while a glass substrate is being applied, SiO₂ or SOG (spin on glass) materials can be used for the sacrificial layer 45. Besides, there are various selections for various ways for integration. For example, as the standard CMOS process is used, the required circuits can be integrated, and the polycrystalline silicon layer, non-crystalline silicon layer, PBSG PSG or any other appropriate interlayer of the same fore process can be used as the sacrificial layer 45, the supporting layer 44, and the lower electrode pattern 42.

FIGS. 5a through 5f are perspective views showing a lower electrode protecting layer is partially defined and applied as a piezoelectrical layer and an etching selectivity interlayer of the lower electrode according to the second embodiment of the present invention. There are differences between this embodiment shown in FIGS. 5a through 5f and the embodiment shown in FIGS. 4a through 4f. That is, the etching window 56 is formed by sacrificial layers 55 one after another according to the present embodiment; and it is not formed by etching the films altogether after the films has been deposited. As shown in FIG. 5a, the bulk acoustic wave device can be formed on a substrate 51. Firstly, a sacrificial layer film 55 is deposited on the substrate, and is defined by micro-image technique. The size of follow-up substrate cavity 50 (as shown in FIG. 5f) will be depended on the geometric size of this sacrificial layer. Afterwards, as shown in FIG. 5b, a supporting layer 54, a lower electrode pattern 52′ are grown or deposited sequentially on this construction, and its geometric patterns are defined by micro-image technique, thus the etching window 56 is maintained open. Then, as shown in FIG. 5c, a lower electrode-protecting layer 57 is deposited, and its geometric pattern is defined by micro-image technique, thus the etching window 56 is kept open. Then, as shown in FIG. 5d, the piezoelectrical layer 53 is deposited, and its pattern is defined by micro-image technique. Since there is no lower electrode protecting layer between the active area A of the bulk acoustic wave device of the piezoelectrical layer 53 and the lower electrode 52′. Therefore, comparing with the prior techniques, the acoustic loss caused by the acoustic wave passing through the lower electrode-protecting layer 57 can be reduced according to the present embodiment. Then, as shown in FIG. 5e, an upper electrode pattern 52 is deposited and defined. At this step, in order to prevent the surface of the piezoelectrical layer 53 from being damaged by the upper electrode etchant, the lift-off technique can be used for defining the pattern of the upper electrode. Meanwhile, a part of the surface of the sacrificial layer 55 is still kept in an exposed status. Afterwards, the sacrificial layer 55 can be removed by dry etching or wet etching, and a sacrificial layer cavity 59 is generated. Finally, as shown in FIG. 5f, the substrate 51 is etched by front-side etching, and a substrate cavity 50 is generated. Consequently, the whole fabrication of the bulk acoustic wave device is completed. The second embodiment, as illustrated above, has advantages; that is, it is unnecessary to etch many materials from various layers. Therefore, the etching gas or etchant need not to be changed while etching, and since the etching time is too long, the problems caused by photo resist that unable to protect completely the lower materials are solved. Moreover, it is ensured that the lower electrode-protecting layer, which causes acoustic energy consumed, would not be generated between the piezoelectrical layer and the lower electrode on the operation region of the device.

FIGS. 6a through 6f are perspective views showing a material having better etching selectivity with AlN is used as the lower electrode according to the third embodiment of the present invention. The whole process is integrated with the advantages of etching the sacrificial layer and the advantages of etching the substrate. There is no etching selectivity interlayer on the acoustic path, so that the quality factor of the surface acoustic wave device would not be influenced, therefore, the follow-up piezoelectrical layer and the upper electrode layer film are well-qualified. As shown in FIG. 6a, the bulk acoustic wave device can be formed on a substrate 61. Firstly, a sacrificial layer film 65 is deposited on the substrate, and a sacrificial layer is defined by micro-image technique. The size of follow-up substrate cavity 60 will be depended on the geometric size of this sacrificial layer. Afterwards, as shown in FIG. 6b, a supporting layer 64, a lower electrode pattern 62′ are formed sequentially on this construction. By means of the techniques presently, since the piezoelectrical layer are mostly applied with AlN and the lower electrode is applied with Al, and the etching selectivity between these two materials is bad, there are difficulties in etching. Therefore, in order to solve this problem, the material having better etching selectivity with AlN, such as gold (Au), chromium (Cr), tungsten (W) or molybdenum (Mo) is used as the lower electrode according to the present embodiment, and the bulk acoustic wave device is operated on a quarter wavelength status. As shown in FIG. 7a, when the lower electrode is grounded, the device is being operated on a quarter wavelength mode, and the partial vibration of the lower electrode is zero that means it is an acoustic wave node. Therefore, even if the high-density material such as Au, Cr, W or Mo is used, the influence to the device properties is still very small. On the contrary, as shown in FIG. 7b, while the lower electrode is floating and non-grounded, and the device is being operated on a semi-wavelength mode. Thus, a maximum vibration generated on the lower electrode part that means it is the peak value of the stationary acoustic wave. Therefore, if the material with high density were used, the acoustic loss would be increased, and the device would be not satisfactory. Then, as shown in FIG. 6b, a piezoelectrical layer 63 is deposited, and its pattern is defined by micro-image technique. Since there is no lower electrode-protecting layer 67 between the piezoelectrical layer 63 and the lower electrode 62′, comparing with the prior techniques, the acoustic loss caused by the acoustic wave passing through the lower electrode-protecting layer 67 can be reduced according to the present embodiment. Then, as shown in FIG. 6c, an upper electrode 62 is deposited and its pattern is defined. At this step, in order to prevent the surface of the piezoelectrical layer 63 from being damaged by the etchant of the upper electrode, the lift-off technique can be used for defining the pattern of the upper electrode. Afterwards, as shown in FIG. 6d, the etching window 66 of the etching sacrificial layer is opened in order to expose a part of the surface of the sacrificial layer 65. Then, as shown in FIG. 6e, the sacrificial layer 65 can be removed by dry etching or wet etching method and a sacrificial layer cavity 69 is generated. Finally, as shown in FIG. 6f, the substrate 61 is etched by front-side etching, and a substrate cavity 60 is generated, thus the construction of the bulk acoustic wave device is released. Consequently, the whole fabrication of the bulk acoustic wave device is completed.

FIGS. 8a through 8f are perspective views showing a material having better etching selectivity with AlN is used as the lower electrode according to the fourth embodiment of the present invention. There are differences between this embodiment shown in FIGS. 8a through 8f and the embodiment shown in FIGS. 6a through 6f. That is, the etching window 86 is formed by sacrificial layers 85 one after another according to the present embodiment; and it is not formed by etching the films altogether after the films has been deposited. As shown in FIG. 8a, the bulk acoustic wave device can be formed on a substrate 81. Firstly, a sacrificial layer film 85 is deposited on the substrate, and is defined by micro-image technique. The size of follow-up substrate cavity 80 will be depended on the geometric size of this sacrificial layer. Afterwards, as shown in FIG. 8b, a supporting layer 84, a lower electrode pattern 82′ are grown or deposited sequentially on this construction, and its geometric patterns are defined by micro-image technique, thus the etching window 86 is maintained open. The material having better etching selectivity with AlN, such as gold (Au), chromium (Cr), tungsten (W) or molybdenum (Mo) is used as the lower electrode according to the present embodiment, and the bulk acoustic wave device is operated on a quarter wavelength status. Then, as shown in FIG. 8c, a piezoelectrical layer 83 is deposited, and its pattern is defined by micro-image technique. Since there is no lower electrode-protecting layer 87 between the piezoelectrical layer 83 and the lower electrode 82′, comparing with the prior techniques, the acoustic loss caused by the acoustic wave passing through the lower electrode-protecting layer 87 can be reduced according to the present invention.

Then, as shown in FIG. 8d, an upper electrode 82 is deposited and its pattern is defined. At this step, in order to prevent the surface of the piezoelectrical layer 83 from being damaged by the etchant of the upper electrode, the lift-off technique can be used for defining the pattern of the upper electrode. Meanwhile, a part of the surface of the sacrificial layer 85 is still maintained an exposed status. Then, as shown in FIG. 8e, the sacrificial layer 85 can be removed by dry etching or wet etching method and a sacrificial layer cavity 89 is generated. Finally, as shown in FIG. 8f, the substrate 81 is etched by front-side etching, and a substrate cavity 80 is generated, thus the construction of the bulk acoustic wave device is released. Consequently, the whole fabrication of the bulk acoustic wave device is completed. The fourth embodiment, as illustrated above, has advantages; that is, it is unnecessary to etch many materials from various layers. Therefore, the etching gas or etchant need not to be changed while etching, and since the etching time is too long, the problems caused by photo resist that unable to protect completely the lower materials are solved. Moreover, it is ensured that the lower electrode-protecting layer, which causes acoustic energy consumed, would not be generated between the piezoelectrical layer and the lower electrode on the operation region of the device.

Besides, FIGS. 9a through 9f are perspective views showing an etching machine with an end point detector is applied, or an AlN layer is applied by the lift-off technique, so that no need for depositing the lower electrode protecting layer according to the fifth embodiment of the present invention. Firstly, as shown in FIG. 9a, a sacrificial layer film 95 is deposited on the substrate 91, and is defined by micro-image technique. Afterwards, as shown in FIG. 9b, a supporting layer 94, a lower electrode pattern 92′ are formed sequentially in this construction. Then, as shown in FIG. 9c, the piezoelectrical layer 93 is deposited, and its pattern is defined by micro-image technique. As shown in FIG. 9d, since an etching machine having a etching-stop detector is applied at this step, the etching depth of the piezoelectrical layer 93 can be controlled accurately, and the lower electrode 92′would not be etched. Alternatively, the lift-off technique can be used for defining the pattern of the piezoelectrical layer; the lower electrode also would not be etched by using the lift-off technique. Then, as shown in FIG. 9e, an upper electrode 92 is deposited and its pattern is defined by the lift-off technique. Afterwards, as shown in FIG. 9f, the etching window 96 of the etching sacrificial layer is opened in order to expose a part of the surface of the sacrificial layer. Finally, as shown in FIG. 9g, the substrate 91 is etched by front-side etching, and a substrate cavity 90 is generated, thus the construction of the bulk acoustic wave device is released. Consequently, the whole fabrication of the bulk acoustic wave device is completed. The fifth embodiment has advantages; that is, the number of the masks and the variety of materials that may be used can be decreased substantially, and there is no lower electrode protecting layer that increasing the acoustic loss between the piezoelectrical layer 93 and the lower electrode 92′.

Although the present invention has been described using specified embodiment, the examples are meant to be illustrative and not restrictive. It is clear that many other variations would be possible without departing from the basic approach, demonstrated in the present invention.

What is claimed is:

1. A manufacturing method for a high quality film bulk acoustic wave device, including the following steps:
depositing and defining a sacrificial layer on the substrate; forming a supporting layer, a lower electrode pattern, a lower electrode protecting layer sequentially;
defining the lower electrode protecting layer by micro-image technique, thus the lower electrode is enabled to be contacted with the follow-up piezoelectrical layer;
depositing a piezoelectrical layer and defining the pattern thereof by micro-image technique;
depositing and defining an upper electrode and the pattern thereof;
opening an etching window of the etching sacrificial layer;
removing the sacrificial layer by dry etching or wet etching, thus a sacrificial layer cavity is generated; and
etching the substrate by front-side etching method.

2. The manufacturing method for a high quality film bulk acoustic wave device as claim 1, wherein the thickness of the sacrificial layer is not more than 5000 Å in order to save the deposition time and keep it smooth.

3. The manufacturing method for a high quality film bulk acoustic wave device as claim 1, wherein the material of the sacrificial layer can be the same as that of the substrate in order to be applied with the same etchant process. For example, as a silicon substrate is applied, polycrystalline silicon or noncrystalline silicon can be used for the sacrificial layer.

4. The manufacturing method for a high quality film bulk acoustic wave device as claim 1, wherein the material of the sacrificial layer can be the same as that of the substrate in order to be applied with the same etchant process. For example, as a glass substrate is applied, silica or SOG (spin on glass) can be used for the sacrificial layer.

5. The manufacturing method for a high quality film bulk acoustic wave device as claim 1, wherein the material of the sacrificial layer can be different from that of the substrate in order to be applied with various etchant processes.

6. A manufacturing method for a high quality film bulk acoustic wave device, including the following steps:
depositing and defining a sacrificial layer on the substrate;
depositing and defining a supporting layer, a lower electrode pattern sequentially on the resulting construction, and maintaining the etching window open;
depositing a lower electrode protecting layer and defining the geometric pattern thereof, and maintaining the etching window open;
depositing a piezoelectrical layer and defining the pattern thereof;
depositing and defining an upper electrode and the pattern thereof;
removing the sacrificial layer by dry etching or wet etching method; and
etching the substrate by front-side etching, thus a substrate cavity is generated.

7. The manufacturing method for a high quality film bulk acoustic wave device as claim 6, wherein the thickness of the sacrificial layer is not more than 5000 Å in order to save the deposition time and keep it smooth.

8. The manufacturing method for a high quality film bulk acoustic wave device as claim 6, wherein the material of the sacrificial layer can be the same as that of the substrate in order to be applied with the same etchant process. For example, as a silicon substrate is applied, polycrystalline silicon or noncrystalline silicon can be used for the sacrificial layer.

9. The manufacturing method for a high quality film bulk acoustic wave device as claim 6, wherein the material of the sacrificial layer can be the same as that of the substrate in order to be applied with the same etchant process. For example, as a glass substrate is applied, silica or SOG (spin on glass) can be used for the sacrificial layer.

10. The manufacturing method for a high quality film bulk acoustic wave device as claim 6, wherein the material of the sacrificial layer can be different from that of the substrate in order to be applied with various etchant processes.

11. A manufacturing method for a high quality film bulk acoustic wave device, including the following steps:
depositing and defining a sacrificial layer on the substrate;
forming a supporting layer;
forming a lower electrode with the material that having better etching selectivity with aluminum nitride (AlN);
defining the lower electrode and the supporting layer in order to open the etching window of the sacrificial layer;
depositing a piezoelectrical layer and defining the pattern thereof;
depositing and defining an upper electrode and the pattern thereof;
opening the etching window of the etched sacrificial layer;
removing the sacrificial layer by dry etching or wet etching method; and
etching the substrate by front-side etching.

12. The manufacturing method for a high quality film bulk acoustic wave device as claim 11, wherein the thickness of the sacrificial layer is not more than 5000 Å in order to save the deposition time and keep it smooth.

13. The manufacturing method for a high quality film bulk acoustic wave device as claim 11, wherein the material of the sacrificial layer can be the same as that of the substrate in order to be applied with the same etchant process. For example, as a silicon substrate is applied, polycrystalline silicon or noncrystalline silicon can be used for the sacrificial layer.

14. The manufacturing method for a high quality film bulk acoustic wave device as claim 11, wherein the material of the sacrificial layer can be the same as that of the substrate in order to be applied with the same etchant process. For example, as a glass substrate is applied, silica or SOG (spin on glass) can be used for the sacrificial layer.

15. The manufacturing method for a high quality film bulk acoustic wave device as claim 11, wherein the material of the sacrificial layer can be different from that of the substrate in order to be applied with various etchant processes.

16. The manufacturing method for a high quality film bulk acoustic wave device as claim 11, wherein the lower electrode layer can be a material select from: gold (Au), chromium (Cr), tungsten (W), or molybdenum (Mo).

17. A manufacturing method for a high quality film bulk acoustic wave device, including the following steps:
depositing and defining a sacrificial layer on the substrate;
forming and defining a supporting layer, and maintaining the etching window of the sacrificial layer open;
forming a lower electrode with the material that having better etching selectivity with aluminum nitride (AlN);
defining the lower electrode, and maintaining the etching window of the sacrificial layer open;
depositing a piezoelectrical layer and defining the pattern thereof;
depositing and defining an upper electrode and the pattern thereof;
removing the sacrificial layer by dry etching or wet etching method; and
etching the substrate by front-side etching.

18. The manufacturing method for a high quality film bulk acoustic wave device as claim 17, wherein the thickness of the sacrificial layer is not more than 5000 Å in order to save the deposition time and keep it smooth.

19. The manufacturing method for a high quality film bulk acoustic wave device as claim 17, wherein the material of the sacrificial layer can be the same as that of the substrate in order to be applied with the same etchant process. For example, as a silicon substrate is applied, polycrystalline silicone or noncrystalline silicon can be used for the sacrificial layer.

20. The manufacturing method for a high quality film bulk acoustic wave device as claim 17 wherein the material of the sacrificial layer can be the same as that of the substrate in order to be applied with the same etchant process. For example, as a glass substrate is applied, silica or SOG (spin on glass) can be used for the sacrificial layer.

21. The manufacturing method for a high quality film bulk acoustic wave device as claim 17, wherein the material of the sacrificial layer can be different from that of the substrate in order to be applied with various etchant processes.

22. The manufacturing method for a high quality film bulk acoustic wave device as claim 17, wherein the lower electrode layer can be a material chosen from: gold (Au), chromium (Cr), tungsten (W), or molybdenum (Mo).

23. A manufacturing method for a high quality film bulk acoustic wave device, including the following steps:
depositing and defining a sacrificial layer on the substrate;
depositing and defining a supporting layer, a lower electrode pattern sequentially on the resulting construction;
depositing a piezoelectrical layer and defining the pattern thereof,
de positing and defining an upper electrode and the pattern thereof,
opening the etching window of the etched sacrificial layer;
removing the sacrificial layer by dry etching or wet etching method; and
etching the substrate by front-side etching.

24. The manufacturing method for a high quality film bulk acoustic wave device as claim 23, wherein the thickness of the sacrificial layer is not more than 5000 Å in order to save the deposition time and keep it smooth.

25. The manufacturing method for a high quality film bulk acoustic wave device as claim 23, wherein the material of the sacrificial layer can be the same as that of the substrate in order to be applied with the same etchant process. For example, as a silicon substrate is applied, polycrystalline silicon or noncrystalline silicon can be used for the sacrificial layer.

26. The manufacturing method for a high quality film bulk acoustic wave device as claim 23 wherein the material of the sacrificial layer can be the same as that of the substrate in order to be applied with the same etchant process. For example, as a glass substrate is applied, silica or SOG (spin on glass) can be used for the sacrificial layer.

27. The manufacturing method for a high quality film bulk acoustic wave device as claim 23, wherein the material of the sacrificial layer can be different from that of the substrate in order to be applied with various etchant processes.

28. The manufacturing method for a high quality film bulk acoustic wave device as claim 23, wherein the piezoelectrical layer can be defined by lift-off method or detecting the etching-end-point method.
